(19) United States
(12) Patent Application Publication
(10) Pub. No.: US 2026/0005603 A1
(43) Pub. Date: Jan. 1, 2026

(54) Frequency Lock Loop for Constant Switching Frequency of DC-DC Converters

(71) Applicant: Reed Semiconductor Corporation, Warwick, RI (US)

(72) Inventors: Jiwei Fan, Cary, NC (US); Yingqian Ma, Shenzhen (CN); Jingyuan Chen, Shenzhen (CN); Hal Chen, Short Hill, NJ (US); Jialun Du, Powell, OH (US)

(21) Appl. No.: 19/322,420

(22) Filed: Sep. 8, 2025

Related U.S. Application Data
(63) Continuation of application No. 17/305,543, filed on Jul. 9, 2021, now Pat. No. 12,431,796.

(51) Int. Cl. H02M 3/04; H02M 3/156; H03L 7/08

(52) U.S. Cl. CPC H02M 3/04; H02M 3/1563; H03L 7/08

(57) ABSTRACT

A frequency lock loop for a constant switching frequency of DC-DC converter, wherein the frequency lock loop includes a modulation circuit to generate a modulation signal in response to an input signal of the DC-DC converter and a frequency signal. Wherein a timer of the DC-DC converter generates a timing signal in response to the input signal, and wherein the frequency signal is a function of the timing signal.

### PRIORITY CLAIM AND CROSS-REFERENCE

This application is a continuation of U.S. patent application Ser. No. 17/305,543, filed on Jul. 9, 2021, entitled “FREQUENCY LOCK LOOP FOR CONSTANT SWITCHING FREQUENCY OF DC-DC CONVERTERS”, which is hereby incorporated herein by reference.

### BACKGROUND OF THE INVENTION

The present invention relates to switching power supplies and, more particularly, a frequency lock loop for constant switching frequency of DC-DC converters.

DC-DC converters play a vital role in efficient power management in various portable devices. However, DC-DC converters are made of non-ideal components and/or arrangements that suffer from parasitic losses and inefficiencies. Accordingly, DC-DC converter components must be carefully specified and physically arranged to achieve stable operation and to keep switching noise (EMI/RFI) at acceptable levels.

One type of DC-DC converter uses constant on-time or constant off-time schemes to control output, and so strives for a constant final switching frequency through different system conditions by regulating/removing a plurality of variable systemic switching frequencies. The switching frequency (FSW) of DC-DC converters can change more than 20% with different Input Voltage (VIN), Output Voltage (VOUT)) and Load Current. When the nominal switching frequency is higher than 2 MHz, the variation can be as large as 40%. The switching frequency change can make power system design challenging and suboptimal, since the output capacitor, power inductor and EMI design are a function of the DC-DC converter's switching frequency.

Adjusting the TON/TOFF based on the VIN, VOUT, ILOAD information, however, is not sufficient nor accurate for common DC-DC converter applications as there are still many variables, like the comparator delay, dead time of the power stage, loss of the power stages, etc., can affect the FSW.

Current methods of regulating switching frequency rely on feed forward information from VIN, VOUT, SW node voltage, etc. A control system which has only feed-forward behavior responds to its control signal in a pre-defined way without responding to how the load reacts. Accordingly, the circuit implementations of these feed forward scheme are complicated, and these feed forward schemes cannot regulate all the variables in a DC-DC converter system which can cause switching frequency modulation.

Moreover, the errors introduced by the feed forward circuits themselves can also bring new FSW variations. For example, feed forward circuits adjusting the TON/TOFF have their own accuracy and non-linearity problems. As a result, while feed forward circuits remove some FSW variation, they also create some new FSW variations. In sum, previous methods cannot optimally remove or regulate the FSW variations.

Turning now to current constant on/off time generator (TON/TOFF generator). designs. Specifically, the TON/TOFF time signal is generated by comparing a Ramp voltage, which is related to VIN and the threshold voltage (Vth), wherein Vth is related to VOUT (for TON) or VIN-VOUT (for TOFF). But generating the TON/TOFF only according to VIN and VOUT information is not enough to keep the final FSW of the DC-DC converter constant through different system conditions. The nonlinearity of Ramp, offset and delay of TON/TOFF comparator, Load change, dead time change, etc, however can all negatively affect the stability of FSW. Previous methods added many circuits to estimate and compensate each of these errors.

As can be seen, there is a need for a frequency lock loop for a constant switching frequency of DC-DC converters utilizing a TON/TOFF generator. The present invention uses a feedback scheme, loop, or path that employs a feedback signal of the FSW that regulates or accounts for all of the systemic variables which induce the FSW changes through adjusting the TON/TOFF width of the TON/TOFF generator, thereby eliminating of the complexity and only feedback the FSW information and adjust.

Specifically, a Frequency Lock Loop (FLL) is added to the constant TON/TOFF generator, wherein the FLL senses the real time switching activities of the DC-DC converters and changes the final switching frequency (FSW) accordingly. In certain embodiments the FSW is changed to a voltage/modulation signal (VFSW) using a modulation circuit and/or a sample and hold circuitry. This switching frequency related voltage signal VFSW will be sent back to the comparator in the TON/TOFF generator together with a reference voltage. With this FLL added, when the FSW is different from a target frequency (reference voltage), the FLL will help to adjust the TON/TOFF width and brings the FSW back to the target frequency.

As a result, the present invention does not need to cover all of the systemic switching frequency variables with complicated circuits. By only feedbacking the switching frequency and adjusting the TON/TOFF comparator, the FSW of DC-DC converter is well controlled. Moreover, the final FSW stability is also much better without the new error introduced by the feedforward circuits.

### SUMMARY OF THE INVENTION

In one aspect of the present invention, a switching power supply controller includes the following: a modulation circuit to generate a modulation signal in response to an input signal and a frequency signal; and a timer to generate a timing signal in response to the input signal, wherein the frequency signal is a function of the timing signal.

In another aspect of the present invention, the switching power supply controller may include wherein a timer input of the timer references a reference voltage and the modulation signal; and further including a comparator operatively associated with the input signal and a threshold voltage, wherein an output of the comparator is connected to said timer input, wherein the modulation circuit and the comparator comprise a frequency feedback loop operatively associated with said timer input, and wherein the timer is a constant on/off time generator.

In yet another aspect of the present invention, a method of removing variable switching frequencies from a direct current to direct current (DC-DC) converter utilizing a constant on/off time generator, the method including operatively associating the frequency feedback loop of the above-mentioned switching power supply controller with the comparator operatively having two input ports associated with the input signal and a threshold voltage, respectively, and wherein an output port of the comparator is electrically coupled to the above-mentioned timer.

These and other features, aspects and advantages of the present invention will become better understood with reference to the following drawings, description and claims.

### BRIEF DESCRIPTION OF THE DRAWINGS

FIG. 1 is a schematic view of an exemplary embodiment a feedback loop of the present invention;

FIG. 2 illustrates example waveforms of signals that may be obtained with the exemplary disclosed system of the present invention; and

FIG. 3 is a schematic view of an exemplary embodiment of a TON/TOFF comparator of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a frequency lock loop for a constant switching frequency of DC-DC converter, wherein the frequency lock loop includes a modulation circuit to generate a modulation signal in response to an input signal of the DC-DC converter and a frequency signal. Wherein a timer of the DC-DC converter generates a timing signal in response to the input signal, and wherein the frequency signal is a function of the timing signal.

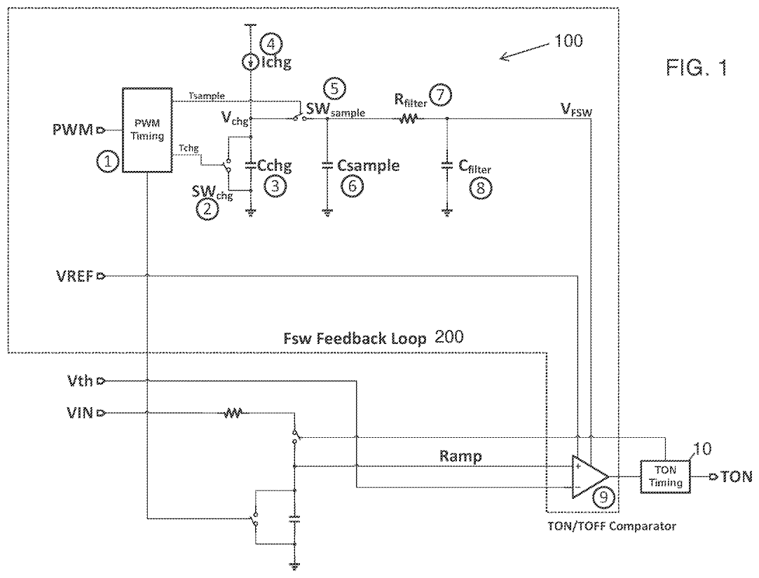

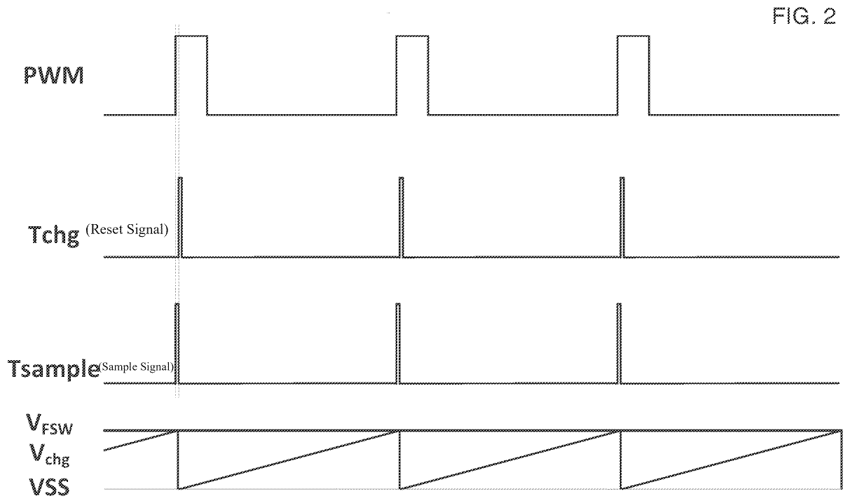

Referring now to FIGS. 1 through 3, the present invention may include a DC-DC converter using constant on-time or constant off-time schemes having modulating or variable switching frequencies, wherein a timing circuit embodying control signals of a pulse-width modulation (PWM) is used to control the output of the power supplied by way of the DC-DC converter. This PWM timing circuitry may be configured to sense the switching frequency from a modulation circuit 100 input signal and generate a timing signal in response to the input signal in such a way that a frequency lock loop so that the switching frequency is affected so that the modulation circuit 100 output signal (VFSW) has the voltage level proportional to the reciprocal of the DC-DC converter's switching frequency, FSW.

Referring to FIG. 1, in certain embodiments, the modulation circuit 100 may include a PWM timing block 1 generating timing signals comprising a Tsample and a Tchg, wherein Tchg is used to control the charging and discharging of a capacitor, Cchg 3, and wherein the Tsample is used to sample the peak voltage on the top terminal of Cchg 3. The modulation circuit 100 may further include a switch, SWchg 2, adapted to control the charge and discharge of the Cchg 3. The capacitor, Cchg 3, may be charged by Ichg when SWchg 2 is open. The modulation circuit 100 may further include a current source, Ichg, which is used to charge Cchg 3.

The modulation circuit 100 may further include the following: a switch, SWsample 5, which will be close at the peak of the charging voltage on Cchg 3; a capacitor, Csample 6, which will sample the peak voltage of Cchg 3; a resistor, Rfilter 7 operatively associated with a capacitor, Cfilter, 8 in such a way as to be configured as a low pass filter Rfilter-Cfilter.

The constant on-time or constant off-time schemes may be implemented by a TON/TOFF generator 10 having an input element operatively associated with a TON/TOFF comparator 9 configured to compare a Ramp voltage, which is related to VIN and the threshold voltage (Vth).

The present invention may be adapted to define a target frequency by way of generating a selectable reference voltage VREF or to a voltage value related to the reference voltage VREF.

The TON/TOFF comparator 9 may configured (or may be reconfigured for methods of improving a pre-existing DC-DC converter using constant on-time or constant off-time schemes) in such a way that the TON/TOFF comparator 9 can adjust its input offset according to the difference between VREF and VFSW.

In certain embodiments, a FSW Feedback Loop/Path or Frequency Lock Loop (FLL) may be operatively associated with the TON/TOFF comparator 9 so that the switching frequency (FSW) is affected by the TON/TOFF width generated by the TON/TOFF generator 10.

For constant TON control scheme, the FSW is determined by the following equation (ignore other small variables): FSW=VOUT/(VIN×TON). For TOFF control, FSW is determined by: FSW=(VIN−VOUT)/(VIN×TOFF).

Again, the FSW may be sensed by the PWM control signal, wherein the PWM timing block 1 generates the Tchg timing signal to control the charging/discharging of Cchg 3. The sample circuit samples the peak voltage of Vchg and holds it with Csample 6. The Low pass filter Rfilter+Cfilter helps to compensate the FSW feedback loop and filter out the sampling noise. After the filter, VFSW and VREF are sent to TON/TOFF comparator 9 to adjust the TON/TOFF time.

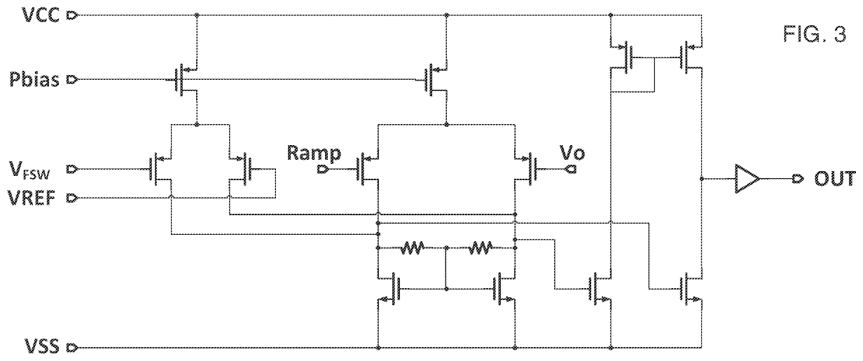

One of the possible implementations of the TON/TOFF comparator 9 is shown in the FIG. 3. Using constant TON Buck Converter as an example, when the FSW is higher than the target frequency, the VFSW will be lower than VREF. The voltage difference between VFSW and VREF will make the TON width larger and the final FSW will be lowered to the target frequency. If the FSW is lower than the target frequency, the difference between VFSW and VREF will make the TON width smaller and make the FSW faster. If the feedback gain is high enough, any FSW variation will be corrected by this FSW feedback loop.

The control circuit disclosed herein may be an integrated silicon chip or build it on PCB using discrete components. Adding some circuitry for FSW frequency selection and trimming of the Ichg may make the control circuit more accurate and support more frequency options.

To use the present invention, one need adds the new FSW Feedback Loop/FLL 200 to a TON/TOFF generator 10 in the constant time DC-DC converter. The present invention can be utilized to create a DC-DC Buck Converter, a DC-DC Boost Converter, and/or a DC-DC Buck-Boost Converter.

It should be understood, of course, that the foregoing relates to exemplary embodiments of the invention and that modifications may be made without departing from the spirit and scope of the invention as set forth in the following claims.

What is claimed is:

1. An apparatus comprising:
a switching power converter including a plurality of power switches; and
a frequency lock loop configured to regulate a switching frequency of the plurality of power switches, the frequency lock loop comprising:
a sample-and-hold circuit configured to sample a signal proportional to the switching frequency;
a filter coupled to the sample-and-hold circuit and configured to generate a frequency feedback signal;
a timer configured to generate a constant on-time signal;
a ramp generator coupled to the timer; and
a comparator configured to compare the frequency feedback signal with a predetermined reference to adjust operation of the plurality of power switches, wherein the frequency lock loop maintains the switching frequency within a target frequency range.

2. The apparatus of claim 1, wherein:
the sample-and-hold circuit is configured to sample a peak voltage proportional to the switching frequency.

3. The apparatus of claim 1, wherein:
the filter comprises a low-pass filter.

4. The apparatus of claim 1, wherein:
the signal is a peak voltage across a sample capacitor, and the sample capacitor is reset by a reset signal, and wherein a leading edge of the constant on-time signal is earlier than a leading edge of the reset signal.

5. The apparatus of claim 1, wherein:
the ramp generator comprises a capacitor charged by an input voltage through a resistor.

6. The apparatus of claim 1, wherein:
the comparator includes a first input configured to receive the frequency feedback signal, a second input configured to receive a reference voltage, a third input configured to receive the ramp signal, and a fourth input configured to receive a threshold voltage.

7. The apparatus of claim 1, wherein:
a leading edge of the constant on-time signal is aligned with a leading edge of a sample signal of the sample-and-hold circuit.

8. A method of regulating a switching frequency of a power converter, comprising:
operating a plurality of power switches of the power converter at a switching frequency;
sampling a signal proportional to the switching frequency;
generating a frequency feedback signal from the sampled signal;
generating a ramp signal;
comparing the frequency feedback signal with a reference voltage signal; and
adjusting an on-time of the power converter in response to the comparison, wherein the method maintains the switching frequency within a predetermined range.

9. The method of claim 8, wherein:
sampling the signal comprises sampling a peak voltage proportional to the switching frequency.

10. The method of claim 8, further comprising:
reducing the on-time when the switching frequency is lower than the predetermined range.

11. The method of claim 8, further comprising:
increasing the on-time when the switching frequency is higher than the predetermined range.

12. The method of claim 8, wherein:
adjusting the on-time comprises providing the frequency feedback signal to a comparator coupled to the timer.

13. The method of claim 8, wherein:
the power converter comprises one of a buck converter, a boost converter, or a buck-boost converter.

14. An integrated circuit comprising:
a pulse width modulation (PWM) timing circuit configured to generate a PWM signal for controlling a plurality of power switches of a power converter;
a sample-and-hold circuit configured to sample a signal proportional to a switching frequency of the power converter;
a filter configured to generate a frequency feedback signal from the sampled signal;
a ramp generator configured to generate a ramp signal; and
a comparator configured to compare the frequency feedback signal with a predetermined reference signal and to adjust timing of the PWM timing circuit, wherein the integrated circuit is configured to form a frequency lock loop that regulates the switching frequency of the power converter.

15. The integrated circuit of claim 14, wherein:
the signal is a peak voltage across a sample capacitor, and the sample capacitor is reset by a reset signal.

16. The integrated circuit of claim 15, wherein:
a falling edge of a sample signal is aligned with a leading edge of the reset signal; and
a leading edge of the sample signal is aligned with a leading edge the PWM signal.

17. The integrated circuit of claim 14, further comprising:
a frequency trim circuit configured to adjust a current flowing into the sample capacitor.

18. The integrated circuit of claim 14, wherein the power converter comprises a buck converter.

19. The integrated circuit of claim 14, wherein the power converter comprises a boost converter.

20. The integrated circuit of claim 14, wherein the power converter comprises a buck-boost converter.
